(19) United States
(12) Patent Application Publication
(10) Pub. No.: US 2014/0099755 A1
(43) Pub. Date: Apr. 10, 2014

(54) FABRICATION METHOD OF STACKED PACKAGE STRUCTURE

(71) Applicant: SILICONWARE PRECISION INDUSTRIES CO., LTD., Taichung (TW)

(72) Inventors: Ping Kai Cheng, Taichung (TW); Wen-Shan Tsai, Taichung (TW)

(73) Assignee: Siliconware Precision Industries Co., Ltd., Taichung (TW)

(21) Appl. No.: 13/729,918

(22) Filed: Dec. 28, 2012

(30) Foreign Application Priority Data
Oct. 9, 2012 (TW) 101137228

(51) Int. Cl. H01L 23/00

(52) U.S. Cl. CPC H01L 24/81
USPC 438/124

(57) ABSTRACT

A fabrication method of a stacked package structure is provided, which includes the steps of: providing a substrate having at least a semiconductor device disposed thereon; and disposing a semiconductor package on the substrate through a plurality of conductive elements such that the semiconductor device is located between the substrate and the semiconductor package, and forming an encapsulant between the substrate and the semiconductor package to encapsulate the semiconductor device. The encapsulant can be formed on the semiconductor package first and then laminated on the substrate to encapsulate the semiconductor device, or alternatively the encapsulant can be filled between the substrate and the semiconductor package driven by a capillary force after the semiconductor package is disposed on the substrate. Therefore, the present invention alleviates pressure and temperature effects on the package to prevent warpage of the substrate and facilitate fabrication of multi-layer stacked package structures.

### BACKGROUND OF THE INVENTION

1. Field of the Invention

The present invention relates to fabrication methods of stacked package structures, and more particularly, to a low-cost fabrication method of a stacked package structure.

2. Description of Related Art

Along with the rapid development of semiconductor packaging technologies, various package types have been developed for semiconductor devices. To improve electrical performance and save space, a plurality of packages are stacked on one another to form a stacked package structure so as to achieve system integration.

FIGS. 1A to 1C are schematic cross-sectional views illustrating a conventional fabrication method of a stacked package structure 1.

Referring to FIG. 1A, a first semiconductor package la having a semiconductor chip 11 is provided. By performing a laser drilling process, a plurality of openings 100 are formed in an encapsulant 13 of the first semiconductor package 1a for exposing first conductive pads 101 of the first semiconductor package 1a.

Referring to FIG. 1B, a plurality of solder bumps 14a are formed on the first conductive pads 101 in the openings 100 of the first semiconductor package 1a. Further, a second semiconductor package 1b having a semiconductor chip (not shown) is provided and a plurality of solder bumps 14b are formed on second conductive pads 102 of the second semiconductor package 1b.

Referring to FIG. 1C, the solder bumps 14b of the second semiconductor package 1b are bonded to the solder bumps 14a of the first semiconductor package 1a and reflowed to form solder joints 14. As such, the second semiconductor package 1b is stacked on and electrically connected to the first semiconductor package 1a.

However, since the laser drilling process has a limited accuracy, a deviation in position may happen to the openings 100 such that the openings 100 are not aligned with the first conductive pads 10. In addition, the solder joints 14 may be adversely affected by the depth of the openings 100. For example, deeper openings 100 may prevent the solder bumps 14a, 14b from coming into contact with each other. On the other hand, shallower openings 100 may do damage to the solder joints 14 due to a bonding pressure or cause adjacent solder joints 14 to come into contact with each other. That is, when the solder bumps 14a, 14b are reflowed, shallower openings 100 may cause the solder material to overflow into adjacent openings, thus resulting in a bridge between the solder joints 14.

Further, according to the above-described method, individual packages are completed first and then the laser drilling and stacking processes are performed to form a stacked package structure. Therefore, the above-described method complicates fabrication process, increases higher fabrication cost, and does not facilitate mass production.

Furthermore, during a molding process for forming the encapsulant of the first semiconductor package 1a or the second semiconductor package 1b, the package 1a, 1b may warp under the influence of processing temperature and pressure, thus adversely affecting alignment and stacking of the packages and preventing fabrication of multi-layered stacked package structures.

Therefore, it becomes urgent for semiconductor packaging industry to overcome the above-described disadvantages nowadays.

### SUMMARY OF THE INVENTION

In view of the above-described disadvantages, the present invention provides a fabrication method of a stacked package structure, which comprises the steps of: providing a substrate having at least a semiconductor device disposed thereon; and disposing a semiconductor package on the substrate through a plurality of conductive elements such that the semiconductor device is located between the substrate and the semiconductor package, and forming an encapsulant between the substrate and the semiconductor package to encapsulate the semiconductor device, wherein the semiconductor package is in contact with the encapsulant.

In an embodiment, the substrate has a plurality of first conductive pads and the semiconductor package has a plurality of second conductive pads that are electrically connected to the first conductive pads through the conductive elements. The conductive elements can be made of solder and copper. Each of the first conductive pads has a recess part.

In the above-described method, the semiconductor device can be a stacked chipset or a single chip.

In the above-described method, the semiconductor device can be electrically connected to the substrate by wire bonding or flip chip attachment.

In the above-described method, the encapsulant can be formed on the semiconductor package first and then encapsulate the semiconductor device when the semiconductor package is disposed on the substrate. In an embodiment, the encapsulant is further formed on the substrate. In an embodiment, the semiconductor package further has an electronic element that is encapsulated by the encapsulant.

In the above-described method, after the semiconductor package is disposed on the substrate, the encapsulant can be filled between the substrate and the semiconductor package to encapsulate the semiconductor device.

In the above-described method, the conductive elements can be conductive bumps, conductive posts or conductive balls.

After the semiconductor device is encapsulated by the encapsulant, the method can further comprise forming another semiconductor package on the semiconductor package.

According to the present invention, after the semiconductor package is disposed on the substrate, the semiconductor device of the substrate is encapsulated by the encapsulant. Therefore, the present invention dispenses with the conventional molding process performed on the substrate, thereby alleviating pressure and temperature effects on the package to prevent warpage of the substrate and facilitate fabrication of multi-layer stacked package structures.

Further, the present invention eliminates the conventional drilling process prior to the step that the semiconductor package is disposed on the substrate facilitating alignment and electrical bonding therebetween.

Therefore, the present invention simplifies fabrication process, shortens processing time, and reduces total cost.

### BRIEF DESCRIPTION OF DRAWINGS

FIGS. 1A to 1C are schematic cross-sectional views illustrating a conventional fabrication method of a stacked package structure;

FIGS. 2A to 2C are schematic cross-sectional views illustrating a fabrication method of a stacked package structure according to a first embodiment of the present invention, wherein FIGS. 2C′ and 2C″ show other embodiments of FIG. 2C;

FIGS. 3A and 3B are schematic cross-sectional views illustrating a fabrication method of a stacked package structure according to a second embodiment of the present invention, wherein FIG. 3B′ shows another embodiment of FIG. 3B;

FIGS. 4A to 4C are schematic cross-sectional views illustrating a fabrication method of a stacked package structure according to a third embodiment of the present invention; and

FIGS. 5A and 5B are schematic cross-sectional views illustrating a fabrication method of a stacked package structure according to a fourth embodiment of the present invention.

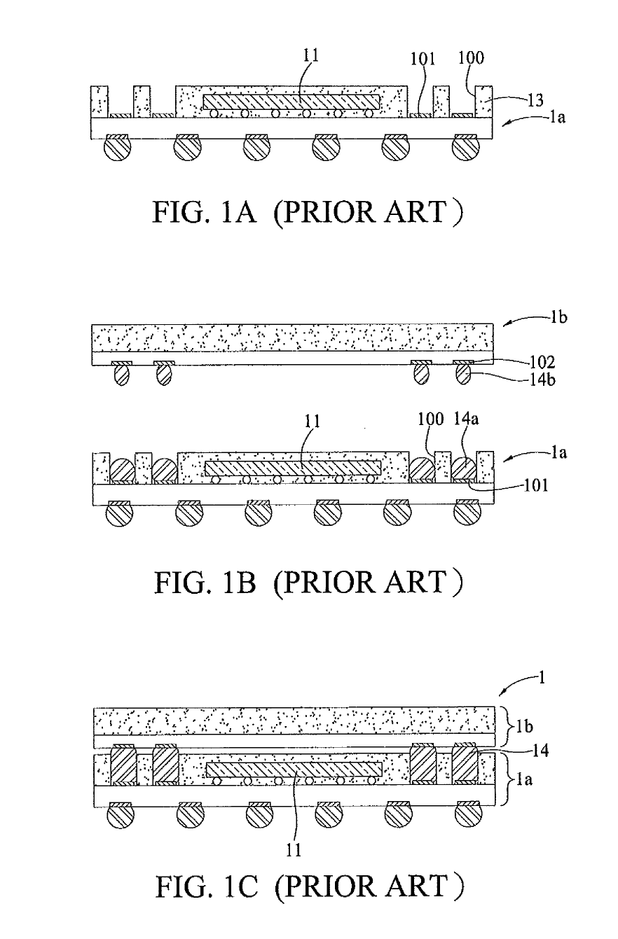

### DETAILED DESCRIPTION OF PREFERRED EMBODIMENTS

The following exemplary embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “first”, “second”, “upper”, “lower”, “a” etc. are merely for illustrative purpose and should not be construed to limit the scope of the present invention.

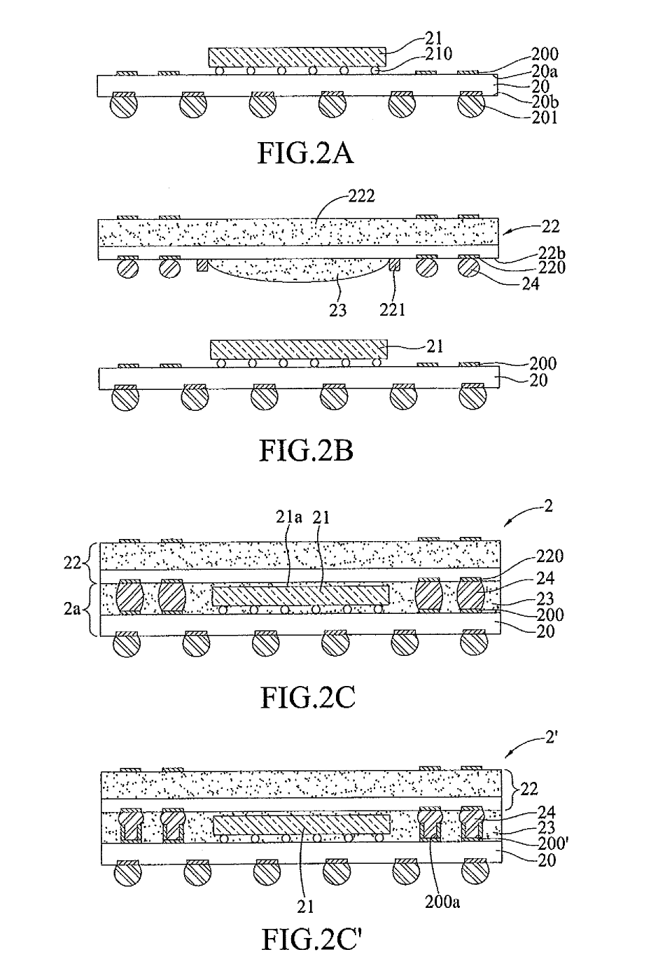

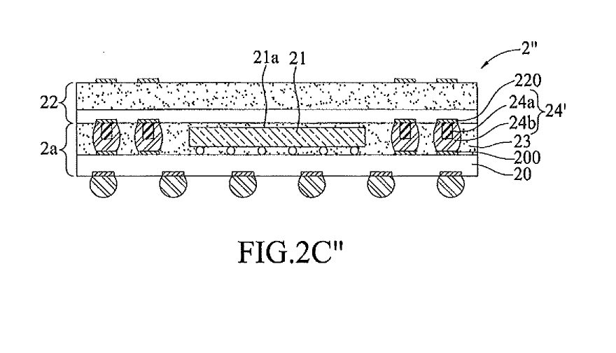

FIGS. 2A to 2C are schematic cross-sectional views illustrating a fabrication method of a stacked package structure 2 according to a first embodiment of the present invention.

Referring to FIG. 2A, a substrate 20 having an upper surface 20a and an opposite lower surface 20b is provided. A semiconductor device 21 is disposed on the upper surface 20a of the substrate 20 and a plurality of first conductive pads 200 are formed on the upper surface 20a of the substrate 20.

In the present embodiment, the semiconductor device 21 is a single chip and flip chip attached to the substrate 20 and electrically connected thereto through a plurality of conductive bumps 210. In other embodiments, the semiconductor device 21 can be electrically connected to the substrate 20 through bonding wires.

The first conductive pads 200 are formed around the periphery of the semiconductor device 21.

The substrate 20 is a packaging substrate having inner layer traces. A plurality of solder balls 201 are formed on the lower surface 20b of the substrate 20 so as for an electronic device such as a circuit board to be disposed thereon.

Referring to FIG. 2B, a first semiconductor package 22 having at least a semiconductor chip (not shown) is provided, and a first encapsulant 23 is formed on a lower surface 22b of the first semiconductor package 22 by performing a dispensing or coating process.

In the present embodiment, the lower surface 22b of the first semiconductor package 22 has a plurality of second conductive pads 220 corresponding in position to the first conductive pads 200. A plurality of conductive elements 24 are formed on the second conductive pads 220, respectively. In another embodiment, the conductive elements 24 can be formed on the first conductive pads 200, respectively.

The conductive elements 24 can be solder bumps or metal posts.

At least a dam 221 is formed on the lower surface 22b of the first semiconductor package 22 so as to limit the spread of the first encapsulant 23 and prevent the first encapuslant 23 from flowing onto traces or the second conductive pads 220.

Further, the dam 221 can be moved towards an edge of the first semiconductor package 22 so as to allow the amount of the first encapsulant 23 in the dam to be increased according to the application requirement. Alternatively, after the process FIG. 2C, more encapsulant can be added from sides through a dispensing process.

Furthermore, the first semiconductor package 22 has an encapsulating material 222 encapsulating the semiconductor chip of the first semiconductor package 22.

Referring to FIG. 2C, the conductive elements 24 are bonded to the first conductive pads 200 to connect the first semiconductor package 22 and the substrate 20. The semiconductor device 21 is located between the substrate 20 and the first semiconductor package 22, and the first encapsulant 23 is laminated between the substrate 20 and the first semiconductor package 22 to encapsulate the semiconductor device 21 and the conductive elements 24. Then, the first encapsulant 23 is cured.

In the present embodiment, the first encapsulant 23 is formed on a top surface 21a of the semiconductor device 21 so as to prevent the top surface 21 a from coming into contact with the first semiconductor package 22. In other embodiments, the first encapsulant 23 is not formed on the top surface 21a of the semiconductor device 21 and the top surface 21a of the semiconductor device 21 is in contact with the first semiconductor package 22.

The first conductive pads 200 and the second conductive pads 220 are electrically connected through the conductive elements 24 so as to electrically connect the first semiconductor package 22 and the substrate 20.

The substrate 20, the semiconductor device 21 and the first encapsulant 23 can be viewed as a lower semiconductor package 2a.

Referring to FIG. 2C′, each of the first conductive pads 200′ has a recess part 200a for increasing the contact area between the first conductive pads 200′ and the conductive elements 24, thereby increasing the bonding force between the first conductive pads 200′ and the conductive elements 24 and improving reliability of the stacked package structure 2′.

The recess parts 200a can be formed by lithography. For example, a photo resist layer or a dry film is formed on the conductive pads and then patterned through exposure and development. Then, a metal material is formed by electroplating and the photoresist is removed to form the recess parts 200a.

In another embodiment, referring to FIG. 2C″, copper bumps 24a are formed on the first conductive pads 200 or the second conductive pads 220 and then a solder material 24b is formed on the copper bumps 24a. Therefore, the copper bumps 24a and the solder material 24b form conductive elements 24′. Each of the conductive elements 24′ comprises at most 85 parts in 100 by weight percent of the copper bump 24a.

The solder material 24b is reflowed to encapsulate the copper bumps 24a so as to increase the contact area between the solder material 24b and copper, i.e., the first conductive pads 200, the second conductive pads 220 and the copper bumps 24a, thereby increasing the bonding force between the conductive elements 24′ and the first conductive pads 200 or the second conductive pads 220 and improving reliability and electrical performance of the conductive elements 24′.

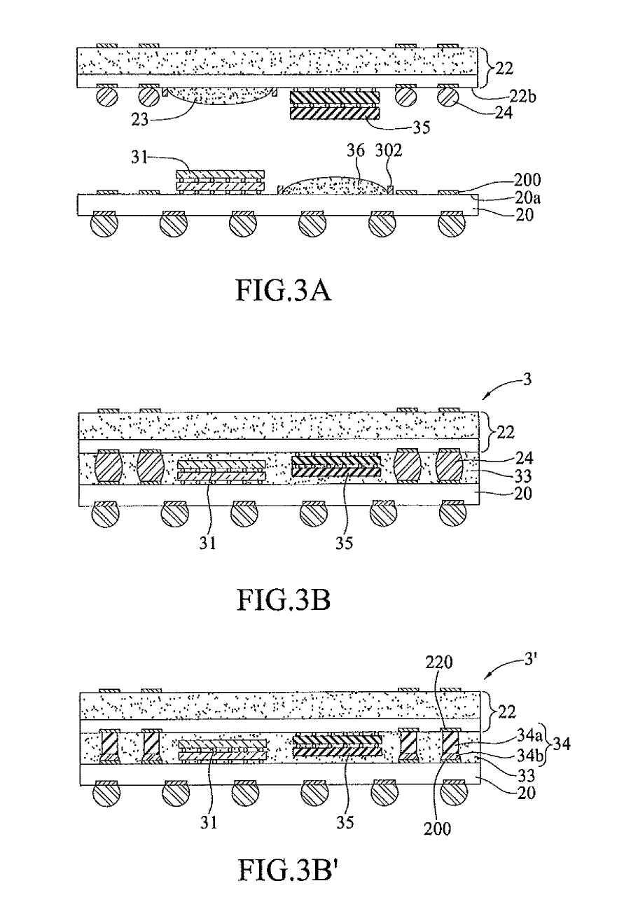

FIGS. 3A and 3B are cross-sectional views illustrating a fabrication method of a stacked package structure 3 according to a second embodiment of the present invention.

Referring to FIG. 3A, the lower surface 22b of the first semiconductor package 22 further has an electronic element 35 disposed thereon and a second encapsulant 36 is further formed on the upper surface 20a of the substrate 20.

In the present embodiment, the semiconductor device 31 and the semiconductor device 35 are stacked chipsets.

Further, at least a dam 302 is formed on the upper surface 20a of the substrate 20 to limit the spread of the second encapsulant 36 and prevent the second encapsulant 36 from flowing onto traces or the first conductive pads 200. The dams 221, 302 can be made of an adhesive. The dams 221, 302 can be made of a material the same as that of the encapsulant. The dams 221, 302 can be made of a semi-cured adhesive. After the package elements are encapsulated by the encapsulant, the dams 221, 302 merge with the first encapsulant 23 (or the encapsulant 33 of FIG. 3B) and then the first encapsulant 23 (or the encapsulant 33) is cured.

The first encapsulant 23 corresponds in position to the semiconductor device 31 and the second encapsulant 36 corresponds in position to the electronic element 35. The first encapsulant 23 and the second encapsulant 36 are made of a same material.

Referring to FIG. 3B, the first semiconductor package 22 is disposed on the substrate 20 through the conductive elements 24 such that both the semiconductor device 31 and the electronic element 35 are located between the substrate 20 and the first semiconductor package 22. The first encapsulant 23 and the second encapsulant 36 form the encapsulant 33 that encapsulates the semiconductor device 31, the electronic element 35 and the conductive elements 24.

In the present embodiment, the encapsulant 33 is formed between the electronic element 35 and the substrate 20. In other embodiments, the electronic element 35 can be in contact with the substrate 20.

Referring to FIG. 3B′, the conductive elements 34 can be made of copper bumps 34a formed on the second conductive pads 220 and a solder material 34b formed on the copper bumps 34a. By performing a reflow process, the solder material 34b is bonded to the first conductive pads 200 without encapsulating the copper bumps 34a.

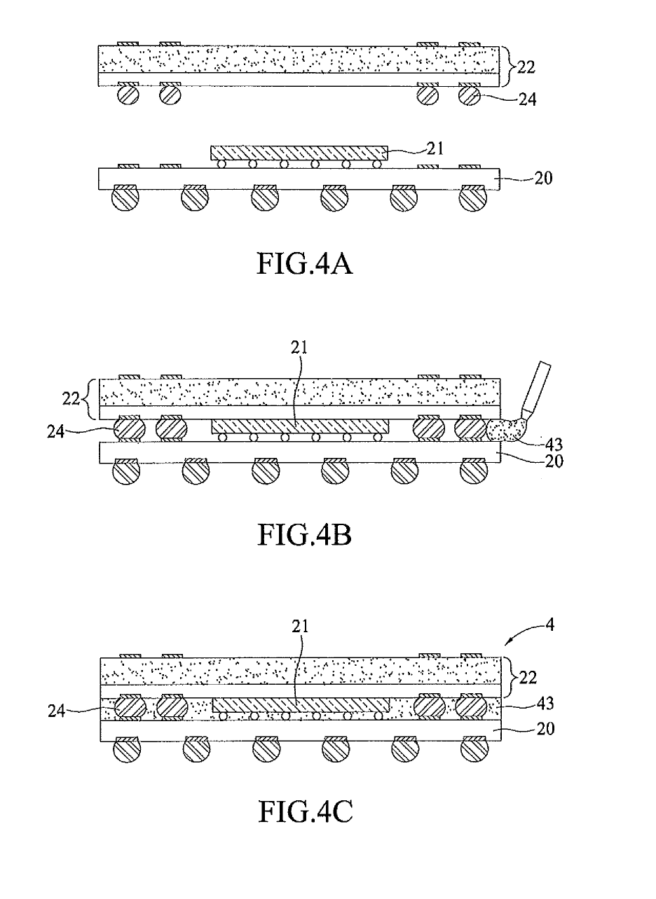

FIGS. 4A to 4C are schematic cross-sectional views illustrating a fabrication method of a stacked package structure 4 according to a third embodiment of the present invention. The present embodiment differs from the first embodiment in the process of forming the first encapsulant 43.

Referring to FIG. 4A, the first semiconductor device 22 is disposed on the substrate 20 through the conductive elements 24.

Referring to FIGS. 4B and 4C, by performing a capillary filling process, the first encapsulant 43 is formed between the substrate 20 and the first semiconductor package 22 to encapsulate the semiconductor device 21 and the conductive elements 24.

Therefore, according to an embodiment of the present invention, the first encapsulant 23 is formed by dispensing and then laminated and cured. In another embodiment, after the semiconductor package is disposed on the substrate, the first encapsulant 43 is filled between the semiconductor package and the substrate and then cured. Compared with the conventional molding process, the dispensing or capillary filling process and the curing process of the present invention have extremely low temperature and pressure, thereby preventing warpage of the lower semiconductor package 2a and facilitating fabrication of multi-layer stack structures.

Further, the present invention dispenses with the conventional drilling process and consequently the conductive elements 24 do not need to be formed in the openings of the encapsulant as in the prior art. Therefore, the first and second conductive pads 200 of larger area can be formed so as to allow a larger alignment deviation error. Hence, the present invention facilitates alignment and electrical bonding of the conductive elements 24 and fabrication of multi-layer stacked package structure 2, 2′, 3, 4.

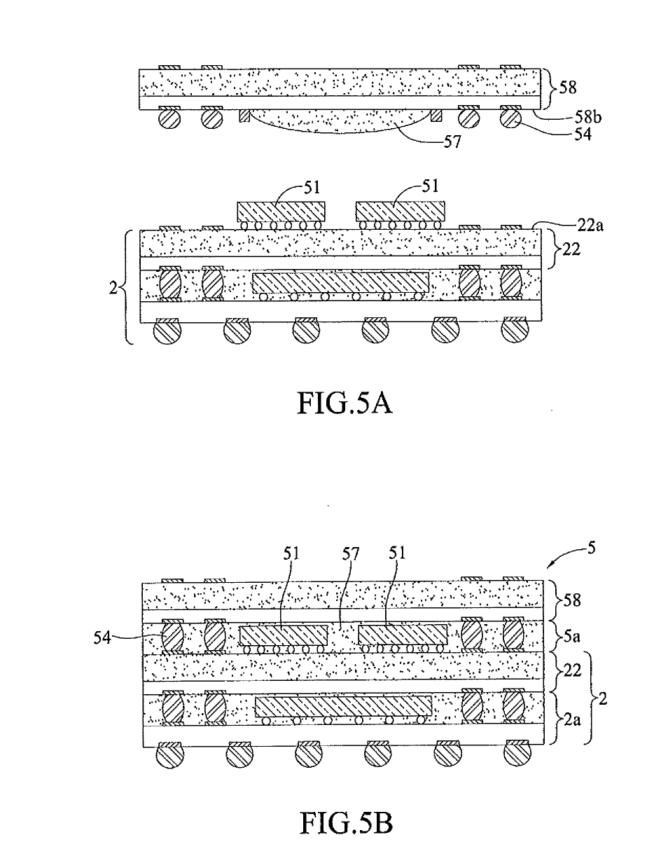

FIGS. 5A and 5B are schematic cross-sectional views illustrating a fabrication method of a stacked package structure 5 according to a fourth embodiment of the present invention. Continued from the first embodiment or the third embodiment, the present embodiment forms another semiconductor package on the stacked package structure 2 or 4 to form a stacked package structure 5.

Referring to FIG. 5A, a plurality of semiconductor devices 51 are disposed on an upper surface 22a of the first semiconductor package 22 of the stacked package structure 2 and a third encapsulant 57 is formed on a lower surface 58b of a second semiconductor package 58.

In the present embodiment, the first encapsulant 23 and the third encapsulant 57 are made of a same material and the semiconductor devices 51 are attached and electrically connected to the first semiconductor package 22 in a chip-chip manner.

The structure of the second semiconductor package 58 is similar to that of the first semiconductor package 22.

Referring to FIG. 5B, the second semiconductor package 58 is disposed on the first semiconductor package 22 through a plurality of conductive elements 54 such that the semiconductor devices 51 are located between the first and second semiconductor packages 22, 58 and encapsulated by the third encapsulant 57. The second semiconductor package 58 is in contact with the third encapsulant 57.

In the present embodiment, the semiconductor devices 51 and the third encapsulant 57 can be viewed as an upper semiconductor package 5a.

In other embodiments, a stacking process can be performed according to the third embodiment. Alternatively, the semiconductor device 51 and the third encapsulant 57 can be omitted and the second semiconductor package 58 is directly disposed and electrically connected to the stacked package structure 2.

Further, the stacked package structure 5 can be formed by alternately performing the processes of the first and third embodiments without being limited to only one stack method.

The second embodiment can also be applied in the fabrication process of the present embodiment.

Therefore, the present invention overcomes the conventional disadvantages, simplifies fabrication process, shortens processing time, and reduces total cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A fabrication method of a stacked package structure, comprising the steps of:
providing a substrate having at least a semiconductor device disposed thereon;
disposing a semiconductor package on the substrate through a plurality of conductive elements such that the at least a semiconductor device is located between the substrate and the semiconductor package, and
forming an encapsulant between the substrate and the semiconductor package to encapsulate the semiconductor device, wherein the semiconductor package is in contact with the encapsulant.

2. The fabrication method of claim 1, wherein the substrate has a plurality of first conductive pads and the semiconductor package has a plurality of second conductive pads electrically connected to the first conductive pads.

3. The fabrication method of claim 2, wherein the second conductive pads are electrically connected to the first conductive pads through the conductive elements.

4. The fabrication method of claim 3, wherein the conductive elements are made of solder and copper.

5. The fabrication method of claim 2, wherein each of the first conductive pads has a recess part.

6. The fabrication method of claim 1, wherein the semiconductor device is a stacked chipset or a single chip.

7. The fabrication method of claim 1, wherein the semiconductor device is electrically connected to the substrate by wire bonding or flip chip attachment.

8. The fabrication method of claim 1, wherein the encapsulant is formed on the semiconductor package first and then encapsulates the semiconductor device when the semiconductor package is disposed on the substrate.

9. The fabrication method of claim 8, wherein the encapsulant is further formed on the substrate.

10. The fabrication method of claim 1, wherein the semiconductor package further has an electronic element that is encapsulated by the encapsulant.

11. The fabrication method of claim 1, wherein after the semiconductor package is disposed on the substrate, the encapsulant is then filled between the substrate and the semiconductor package to encapsulate the semiconductor device.

12. The fabrication method of claim 1, wherein the conductive elements are conductive bumps, conductive posts, or conductive balls.

13. The fabrication method of claim 1, after the semiconductor device is encapsulated by the encapsulant, further comprising forming another semiconductor package on the semiconductor package.
